(19) United States
(12) Patent Application Publication
(10) Pub. No.: US 2014/0077240 A1
(43) Pub. Date: Mar. 20, 2014

(54) IV MATERIAL PHOTONIC DEVICE ON DBR

(71) Applicants: Radek Roucka, Mountain View, CA (US); Michael Lebby, Apache Junction, AZ (US); Scott Semans, Sunnyvale, CA (US); Andrew Clark, Los Altos, CA (US)

(72) Inventors: Radek Roucka, Mountain View, CA (US); Michael Lebby, Apache Junction, AZ (US); Scott Semans, Sunnyvale, CA (US); Andrew Clark, Los Altos, CA (US)

(21) Appl. No.: 13/621,413

(22) Filed: Sep. 17, 2012

(51) Int. Cl. H01L 31/0232; H01L 33/46

(52) U.S. Cl. CPC H01L 31/0232; H01L 33/46
USPC 257/98; 438/29; 438/72; 257/432

(57) ABSTRACT

A photonic structure including a substrate of either crystalline silicon or germanium and a multilayer distributed Bragg reflector (DBR) positioned on the substrate. The DBR includes material substantially crystal lattice matching the DBR to the substrate. The DBR includes a plurality of pairs of layers of material including any combination of IV materials and any rare earth oxide (REO). A photonic device including multilayers of single crystal IV material positioned on the DBR and including material substantially crystal lattice matching the DBR to the photonic device.

### FIELD OF THE INVENTION

This invention relates in general to the formation of photonic/photovoltaic devices on a reflective template.

### BACKGROUND OF THE INVENTION

In the photonic industry, it is known that various germanium (Ge) alloys and mixtures (IV materials) are desirable materials useful in photonic and photovoltaic devices for detection and emission of light. Si and Ge templates are used for the subsequent growth of IV materials used in many photonic/electronic devices. In particular SiGeSn alloys and GeSn alloys are synthesized on Si and Ge wafers. The major problem is that both Si and Ge absorb light so that any light emitted in a reverse direction or otherwise passing through a photonic or photovoltaic device is absorbed and therefore lost. For example, in multijunction solar cells utilizing SiGeSn or GeSn materials as the PV junction, certain portions of the light are transmitted through the device toward the underlying substrate due to short absorption lengths. This light is then absorbed by the substrate and lost to the conversion process.

It would be highly advantageous, therefore, to remedy the foregoing and other deficiencies inherent in the prior art.

Accordingly, it is an object of the present invention to provide new and improved methods for the growth of single crystal IV materials on a reflective template.

It is another object of the present invention to provide new and improved methods of fabricating photonic or photovoltaic device including IV materials on silicon or germanium templates/substrates.

It is another object of the present invention to provide new and improved photonic or photovoltaic devices including IV materials on silicon or germanium templates/substrates.

### SUMMARY OF THE INVENTION

Briefly, the desired objects and aspects of the instant invention are achieved in accordance with a preferred method of fabricating a photonic device on a silicon or germanium substrate including providing a substrate of either crystalline silicon or germanium, epitaxially growing a multilayer distributed Bragg reflector on the substrate, and epitaxially growing a photonic device including multilayers of single crystal IV material on the distributed Bragg reflector.

The desired objects and aspects of the instant invention are also realized in accordance with a specific method of fabricating a photonic device on either a silicon or germanium substrate including providing a substrate of either crystalline silicon or germanium and epitaxially growing a multilayer distributed Bragg reflector on the substrate. The step including selecting material substantially crystal lattice matching the multilayer distributed Bragg reflector to the substrate. The method further includes a step of epitaxially growing a photonic device that includes multilayers of single crystal IV material on the distributed Bragg reflector. The step includes selecting material substantially crystal lattice matching the multilayer distributed Bragg reflector to the photonic device.

The desired objects and aspects of the instant invention are also realized in accordance with a specific embodiment of a photonic structure including a substrate of either crystalline silicon or germanium and a multilayer distributed Bragg reflector positioned on the substrate. A photonic device including multilayers of single crystal IV material is positioned on the distributed Bragg reflector.

The desired objects and aspects of the instant invention are further realized in accordance with a specific embodiment of a photonic structure including a substrate of either crystalline silicon or germanium and a multilayer distributed Bragg reflector (DBR) positioned on the substrate. The DBR includes material substantially crystal lattice matching the DBR to the substrate and a plurality of pairs of layers of material including any combination of IV materials and any rare earth oxide (REO). A photonic device including multilayers of single crystal IV material is positioned on the DBR and includes material substantially crystal lattice matching the DBR to the photonic device.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the drawings, in which:

FIG. 1 is a simplified layer diagram of a IV material photonic device with a DBR on a Si or Ge structure in accordance with the present invention; and

FIG. 2 is a graph representing the reflectivity of the DBR of FIG. 1.

### DETAILED DESCRIPTION OF THE DRAWINGS

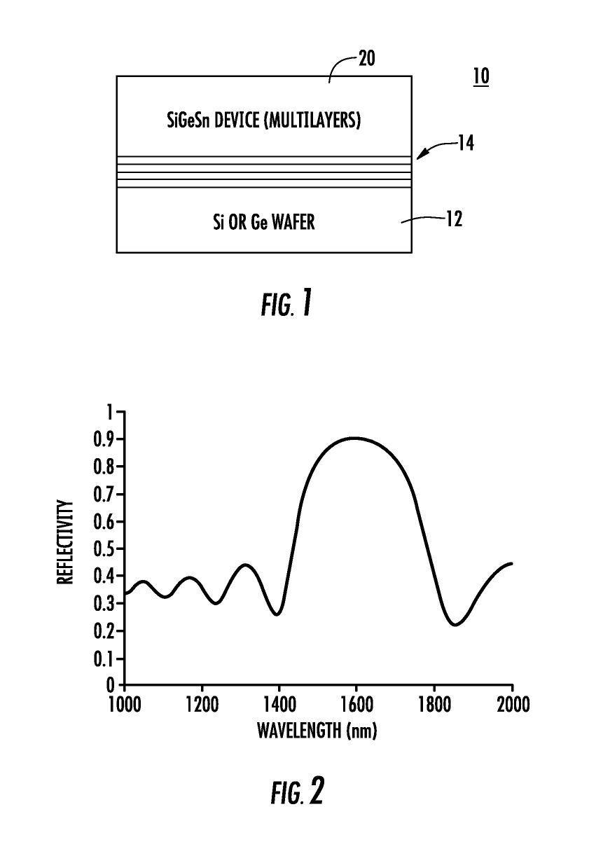

Turning to FIG. 1, a simplified layer diagram of a IV material photonic structure, generally designated 10, includes a Si or Ge structure 12 as illustrated. Structure 12 includes a single crystal silicon or germanium wafer which, it will be understood, is or may be a standard well know single crystal wafer or portion thereof generally known and used in the semiconductor industry. Single crystal substrates, it will be understood, are not limited to any specific crystal orientation but could include <111> silicon, <110> silicon, <100> silicon or any other orientation or variation known and used in the art.

Generally, when a silicon substrate is used, structure 12 includes a crystal lattice matching template formed on the surface to aid in the growth of high quality single crystal germanium thereon. Examples of templates that could be incorporated into structure 12 can be seen in copending United States patent application entitled “Si—Ge—Sn on REO Template” bearing Ser. No. 13/619,736, and filed 14 Sep. 2012 and copending United States patent application entitled “Delta Doping at Si—Ge Interface” bearing Ser. No. 13/619,883, and filed 14 Sep. 2012.

A quarter wavelength distributed Bragg reflector (DBR) 14 is epitaxially grown on structure 12 and, as understood in the art, includes a material system generally consisting of two materials having different indices of refraction forming pairs of reflective layers and usually easily lattice matched to structure 12. Generally, DBR 14 can be made of any combination of Si, Ge, GeSn, SiGeSn (hereinafter referred to as IV materials) and any rare earth oxide (REO) such as Gd₂O₃, Er₂O₃, Nd₂O₃, Y₂O₃ Pr₂O₃, etc. Throughout this disclosure whenever rare earth materials are mentioned it will be understood that “rare earth” materials are generally defined as any of the lanthanides as well as scandium and yttrium.

The structure of DBR 14 is engineered to be substantially crystal lattice matched to structure 12 and to a photonic device 20 grown on the upper surface. Further, the composition of pairs of layers, thicknesses of layers, and sequence of materials and layers in DBR 14 are all engineered to be reflective within a band of wavelengths required by photonic device 20 (e.g. an operating wavelength). An example of engineered reflectivity of a DBR is illustrated in FIG. 2. In this example the DBR is constructed of multilayers containing Si and Ge and has a maximum reflectivity at wavelengths around 1600 nm. The DBR can be constructed of any combination of the following materials 1) REO/GeSn 2) REO/SiGeSn 3) REO/Ge 4) REO/GeSi A DBR with engineered reflectivity as shown in FIG. 2 is included as DBR 14 in FIG. 1 and can include a Ge or GeSn bottom layer and/or as a top layer with photonic device 20 including GeSn/SiGeSn alloys or any of the IV materials.

In photonic or photovoltaic devices, including multijunction solar cells, utilizing IV materials, such as SiGeSn or GeSn, as PV junctions, (herein referred to simply as “photonic devices”) certain portions of light are transmitted through the junction or layers of materials due to short absorption lengths. That is, most of the IV material layers in photonic device 20 are approximately 3 nm to approximately 5 nm thick. In light absorbing devices (detectors) or light emitting devices (lasers LEDs, etc.) a portion of the light transmitted or emitted is directed toward the substrate where it is absorbed by the Si or Ge. Insertion of reflector (DBR) 14 between substrate 12 and photonic device 20 reflects the light away from substrate 12 and back into photonic device 20 where it is converted into electrical carriers. Thus, implementation of reflector 14 in photonic structure 10 allows for higher efficiency photonic devices.

Thus, new and improved methods for the fabrication of photonic devices on single crystal substrates are disclosed, which methods include new and improved methods for the growth of single crystal IV materials on a reflective template. Also, new and improved methods of fabricating photonic device are disclosed including growing IV materials on silicon or germanium templates/substrates. Further, new and improved photonic or photovoltaic devices are disclosed including IV materials grown on silicon or germanium templates/substrates.

Various changes and modifications to the embodiments herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. A method of fabricating a photonic device on a silicon or germanium substrate comprising the steps of:
providing a substrate including one of crystalline silicon or germanium;
epitaxially growing a multilayer distributed Bragg reflector on the substrate; and
epitaxially growing a photonic device including multilayers of single crystal IV material on the distributed Bragg reflector.

2. A method as claimed in claim 1 wherein the step of epitaxially growing the multilayer distributed Bragg reflector includes epitaxially growing a plurality of pairs of layers of material including any combination of IV materials and any rare earth oxide (REO).

3. A method as claimed in claim 2 wherein the step of epitaxially growing a plurality of pairs of layers of material including any combination of IV materials includes any one of Si, Ge, GeSn, SiGeSn, and combinations thereof.

4. A method as claimed in claim 2 wherein the step of epitaxially growing a plurality of pairs of layers of material including any combination of any rare earth oxide (REO) includes any one of Gd₂O₃, Er₂O₃, Nd₂O₃, Y₂O₃ Pr₂O₃, and combinations thereof.

5. A method as claimed in claim 1 wherein the step of epitaxially growing the multilayer distributed Bragg reflector includes selecting material substantially crystal lattice matching the multilayer distributed Bragg reflector to the photonic device.

6. A method as claimed in claim 1 wherein the step of epitaxially growing the multilayer distributed Bragg reflector includes selecting material substantially crystal lattice matching the multilayer distributed Bragg reflector to the substrate.

7. A method as claimed in claim 6 wherein the step of selecting material substantially crystal lattice matching the multilayer distributed Bragg reflector to the substrate includes epitaxial growing a crystal lattice matching template between the multilayer distributed Bragg reflector and the substrate.

8. A method as claimed in claim 1 wherein the step of epitaxially growing the multilayer distributed Bragg reflector includes engineering a composition of pairs of layers, thicknesses of layers, and sequence of materials and layers in the multilayer distributed Bragg reflector to be reflective within a band of wavelengths required by the photonic device.

9. A method as claimed in claim 8 wherein the step of epitaxially growing the multilayer distributed Bragg reflector includes engineering the thicknesses of the pairs of layers to grow the multilayer distributed Bragg reflector one quarter wavelength thick at an operating wavelength of the photonic device.

10. A method of fabricating a photonic device on a silicon or germanium substrate comprising the steps of:
providing a substrate including one of crystalline silicon or germanium;
epitaxially growing a multilayer distributed Bragg reflector on the substrate, the step including selecting material substantially crystal lattice matching the multilayer distributed Bragg reflector to the substrate; and
epitaxially growing a photonic device including multilayers of single crystal IV material on the distributed Bragg reflector, the step including selecting material substantially crystal lattice matching the multilayer distributed Bragg reflector to the photonic device.

11. A method as claimed in claim 10 wherein the step of selecting material substantially crystal lattice matching the multilayer distributed Bragg reflector to the substrate includes epitaxial growing a crystal lattice matching template between the multilayer distributed Bragg reflector and the substrate.

12. A photonic structure comprising:
a substrate including one of crystalline silicon or germanium;
a multilayer distributed Bragg reflector positioned on the substrate; and
a photonic device including multilayers of single crystal IV material positioned on the distributed Bragg reflector.

13. A photonic structure as claimed in claim 12 wherein the multilayer distributed Bragg reflector includes a plurality of pairs of layers of material including any combination of IV materials and any rare earth oxide (REO).

14. A photonic structure as claimed in claim 13 wherein the plurality of pairs of layers of material includes any one of Si, Ge, GeSn, SiGeSn, and combinations thereof.

15. A photonic structure as claimed in claim 13 wherein the plurality of pairs of layers of material include any one of Gd₂O₃, Er₂O₃, Nd₂O₃, Y₂O₃ Pr₂O₃, and combinations thereof.

16. A photonic structure as claimed in claim 12 wherein the multilayer distributed Bragg reflector includes material substantially crystal lattice matching the multilayer distributed Bragg reflector to the photonic device.

17. A photonic structure as claimed in claim 12 wherein the multilayer distributed Bragg reflector includes material substantially crystal lattice matching the multilayer distributed Bragg reflector to the substrate.

18. A photonic structure as claimed in claim 17 wherein the material substantially crystal lattice matching the multilayer distributed Bragg reflector to the substrate includes a crystal lattice matching template positioned between the multilayer distributed Bragg reflector and the substrate.

19. A photonic structure as claimed in claim 12 wherein the multilayer distributed Bragg reflector includes a composition of pairs of layers, thicknesses of layers, and sequence of materials and layers selected to be reflective within a band of wavelengths required by the photonic device.

20. A photonic structure as claimed in claim 19 wherein the multilayer distributed Bragg reflector includes thicknesses of the pairs of layers one quarter wavelength thick at an operating wavelength of the photonic device.

21. A photonic structure comprising:
a substrate including one of crystalline silicon or germanium;
a multilayer distributed Bragg reflector positioned on the substrate and including material substantially crystal lattice matching the multilayer distributed Bragg reflector to the substrate, the multilayer distributed Bragg reflector including a plurality of pairs of layers of material including any combination of IV materials and any rare earth oxide (REO); and
a photonic device including multilayers of single crystal IV material positioned on the distributed Bragg reflector and including material substantially crystal lattice matching the multilayer distributed Bragg reflector to the photonic device.

22. A photonic structure as claimed in claim 21 wherein the material substantially crystal lattice matching the multilayer distributed Bragg reflector to the substrate includes a crystal lattice matching template positioned between the multilayer distributed Bragg reflector and the substrate.
